(19) United States
(12) Patent Application Publication
(10) Pub. No.: US 2026/0338706 A1
(43) Pub. Date: Oct. 29, 2026

(54) COMPUTATIONAL-BASED CORRECTION OF ABERRATIONS AND MASK 3D EFFECTS FOR APPLICATIONS INCLUDING EXTREME ULTRAVIOLET (EUV) SCANNER FOCUS METROLOGY AND CONTROL

(71) Applicant: KLA Corporation, Milpitas, CA (US)

(72) Inventors: Roel GRONHEID, Leuven (BE); Alessandro VAGLIO PRET, Gorgonzola (IT); Huan REN, Shanghai (CN); Boris Johan Louis HABETS, Dresden (DE)

(21) Appl. No.: 19/650,154

(22) Filed: Apr. 16, 2026

Related U.S. Application Data
(60) Provisional application No. 63/794,333, filed on Apr. 25, 2025.

(51) Int. Cl. G01N 21/956; G01N 21/21; G01N 23/2251; G03F 1/22; G03F 7/00; G03F 7/20

(52) U.S. Cl. CPC G01N 21/956; G01N 21/211; G01N 23/2251; G03F 1/22; G03F 7/2004; G03F 7/70033; G03F 7/70516; G03F 7/706; G03F 7/70655; G03F 7/706837; G03F 7/706841; G03F 7/706849; G01N 2021/95676; G01N 2201/127; G01N 2223/611

(57) ABSTRACT

Systems and methods for determining information for a lithography process are provided. One system includes a computer system configured for acquiring characteristic(s) of a specimen exposed to a pattern of light in a slit of the light scanned over the specimen during a lithography process. The computer system is also configured for determining parameter(s) with which the lithography process was performed at two or more of different positions within the slit based on the acquired characteristic(s) and a predetermined relationship between the parameter(s) at the different positions within the slit and simulated characteristic(s) of the specimen at different positions on the specimen corresponding to the different positions within the slit. In addition, the computer system is configured for determining information for the lithography process based on the determined parameter(s).

### BACKGROUND OF THE INVENTION

### 1. Field of the Invention

The present invention generally relates to systems and methods for determining information for a lithography process. Certain embodiments are configured for computational-based correction of aberrations and mask three-dimensional (3D) effects for applications including extreme ultraviolet (EUV) scanner focus metrology and control.

### 2. Description of the Related Art

The following description and examples are not admitted to be prior art by virtue of their inclusion in this section.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

Metrology processes are used at various steps during a semiconductor manufacturing process to monitor and control the process. Metrology processes are different than inspection processes in that, unlike inspection processes in which defects are detected on a specimen, metrology processes are used to measure one or more characteristics of the specimen that cannot be determined using currently used inspection tools. For example, metrology processes are used to measure one or more characteristics of a specimen such as a dimension (e.g., line width, thickness, etc.) of features formed on the specimen during a process such that the performance of the process can be determined from the one or more characteristics. In addition, if the one or more characteristics of the specimen are unacceptable (e.g., out of a predetermined range for the characteristic(s)), the measurements of the one or more characteristics of the specimen may be used to alter one or more parameters of the process such that additional specimens manufactured by the process have acceptable characteristic(s).

Metrology processes are also different than defect review processes in that, unlike defect review processes in which defects that are detected by inspection are re-visited in defect review, metrology processes may be performed at locations at which no defect has been detected. In other words, unlike defect review, the locations at which a metrology process is performed on a specimen may be independent of the results of an inspection process performed on the specimen. In particular, the locations at which a metrology process is performed may be selected independently of inspection results. In addition, locations on the specimen at which metrology is performed may be selected independently of inspection results. In this manner, the locations at which the metrology process is performed may be determined before an inspection process has been performed on the specimen. In contrast, in defect review, the locations on the specimen at which defect review is to be performed cannot be determined until the inspection results for the specimen are generated and available for use.

Existing methods for focus metrology include optical as well as scanning electron microscope (SEM) based techniques. Optical techniques typically employ one or multiple targets while SEM based techniques may work on a target or on device pattern. In all cases, the measured signal comes from pattern critical dimension (CD), profile, and/or placement variation through focus. The response of the measured signal through focus is calibrated using focus-exposure matrix (FEM) or focus-stripe wafers. These wafers are printed to have a systematic variation of focus across the wafer, and the focus signal from the metrology technique of choice is calibrated against the programmed focus variation.

The currently used methods for focus control have a number of important disadvantages. For example, focus can be considered a low order lens aberration. One of the problems of the techniques described above is that higher order lens aberrations (e.g., COMA) can have substantially similar patterning effects (especially CD variations and pattern placement errors (PPEs)). In addition, these aberrations are not constant through the slit. Finally, especially in extreme ultraviolet (EUV) lithography, mask 3D effects (including mask shadowing) behave similarly to the aforementioned aberrations. The mask 3D effects also show a distinct through slit behavior, which is different for different geometries (e.g., pitch) or orientation of the pattern on mask. As a result, the calibration curves will be slit position and pattern dependent (experimental data demonstrates this behavior). For obtaining across-slit focus behavior, generating multiple calibration curves specific for each considered pattern is therefore needed.

The through slit and pattern behavior of both aberrations and mask 3D effects and their impact on pattern CD and placement are strongly illuminator dependent. For each lithography layer (which are typically exposed with different illuminator source shapes) then, the through slit behavior will be different. Additionally, aberrations may change over time on relatively short time scales (lens heating) or relatively long time scales (optics ageing/contamination). The illuminator may also show variations (such as shape and intensity) through slit and/or over time. The currently used methods would require reconstruction of the calibration curves. Furthermore, through slit and pattern behavior is sensitive to the mask stack, e.g., any change in mask topography geometry and optical properties leads to different behaviors of the abovementioned effects.

Accordingly, it would be advantageous to develop systems and methods for determining information for a lithography process that do not have one or more of the disadvantages described above.

### SUMMARY OF THE INVENTION

The following description of various embodiments is not to be construed in any way as limiting the subject matter of the appended claims.

One embodiment relates to a system configured for determining information for a lithography process. The system includes a computer system configured for acquiring one or more characteristics of a specimen exposed to a pattern of light in a slit of light scanned over the specimen during a lithography process. The computer system is also configured for determining one or more parameters with which the lithography process was performed at two or more of different positions within the slit based on the acquired one or more characteristics and a predetermined relationship between the one or more parameters at the different positions within the slit and one or more simulated characteristics of the specimen at different positions on the specimen corresponding to the different positions within the slit. In addition, the computer system is configured for determining information for the lithography process based on the determined one or more parameters. The system may be further configured as described herein.

Another embodiment relates to a computer-implemented method for determining information for a lithography process. The method includes the acquiring, determining one or more parameters, and determining information steps described above, which are performed by a computer system. Each of the steps of the method may be further performed as described further herein. The method may include any other step(s) of any other method(s) described herein. The method may be performed by any of the systems described herein.

An additional embodiment relates to a non-transitory computer-readable medium storing program instructions executable on a computer system for performing a computer-implemented method for determining information for a lithography process. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Further advantages of the present invention will become apparent to those skilled in the art with the benefit of the following detailed description of the preferred embodiments and upon reference to the accompanying drawings in which:

FIGS. 1 and 2 are schematic diagrams illustrating side views of embodiments of a system configured for determining information for a lithography process;

FIG. 3 is a flow chart illustrating one embodiment of a setup phase of a computer-implemented method for determining information for a lithography process;

FIG. 4 is a flow chart illustrating one embodiment of a runtime phase of the computer-implemented method for determining information for a lithography process; and

FIG. 5 is a block diagram illustrating one embodiment of a non-transitory computer-readable medium storing program instructions for causing a computer system to perform a computer-implemented method described herein.

While the invention is susceptible to various modifications and alternative forms, specific embodiments thereof are shown by way of example in the drawings and are herein described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

In general, the embodiments described herein are configured for determining information for a lithography process. In lithography, an exposure tool is configured for exposing resist on wafers. The exposure may be performed with a so-called step-and-scan process during which individual exposure fields on a wafer are scanned with a slit of light. After scanning the complete exposure field, the system steps to the next field. A critical parameter that is preferably controlled during the exposure is the focus.

Several methods for focus metrology (either on monitor wafers or on-product) have been presented in literature and/or commercialized. All such methods have in common that they rely on a response to focus of pattern critical dimension (CD), profile, placement, or a combination thereof. All methods start by calibrating the measured response using programmed focus offset. The embodiments described herein aim to improve ease, accuracy, and turnaround time of the calibration procedure via simulation or a combination of simulation and experiment.

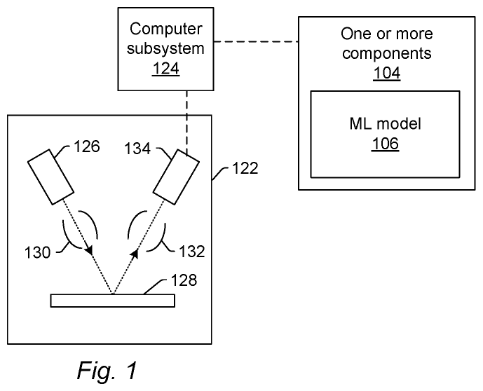

One embodiment relates to a system configured for determining information for a lithography process. One embodiment of the system is shown in FIG. 1. The system includes tool 122. The tool includes and/or is coupled to a computer subsystem, e.g., computer subsystem 124. In general, the tools described herein include at least an energy source, a detector, and a scanning subsystem. The energy source is configured to generate energy that is directed to a specimen by the tool. The detector is configured to detect energy from the specimen and to generate output responsive to the detected energy. The scanning subsystem is configured to change a position on the specimen to which the energy is directed and from which the energy is detected.

The specimen(s) described herein may be wafers. The wafers may include any wafers known in the semiconductor arts. In addition, the embodiments described herein may be used for specimens such as reticles, flat panels, personal computer (PC) boards, and other semiconductor specimens.

As shown in FIG. 1, the tool may be configured as an electron-based tool such as a scanning electron microscope (SEM). In an electron beam tool, the energy directed to the specimen includes electrons, and the energy detected from the specimen includes electrons. As shown in FIG. 1, the tool includes electron column 122, and the system includes computer subsystem 124 coupled to the tool. Computer subsystem 124 may be configured as described herein. In addition, such a tool may be coupled to another one or more computer systems (not shown) in any manner known in the art.

As also shown in FIG. 1, the electron column includes electron beam source 126 configured to generate electrons that are focused to specimen 128 by one or more elements 130. The electron beam source may include, for example, a cathode source or emitter tip, and one or more elements 130 may include, for example, a gun lens, an anode, a beam limiting aperture, a gate valve, a beam current selection aperture, an objective lens, and a scanning subsystem, all of which may include any such suitable elements known in the art.

Electrons returned from the specimen (e.g., secondary electrons) may be focused by one or more elements 132 to detector 134. One or more elements 132 may include, for example, a scanning subsystem, which may be the same scanning subsystem included in element(s) 130. The detector may detect electrons returned from the surface of the specimen thereby forming electron beam images of (or other output for) the specimen. The electron beam images may include any suitable electron beam images.

The electron column may include any other suitable elements known in the art. In addition, the electron column may be further configured as described in U.S. Pat. No. 8,664,594 issued Mar. 4, 2014 to Jiang et al., U.S. Pat. No. 8,692,204 issued Apr. 8, 2014 to Kojima et al., U.S. Pat. No. 8,698,093 issued Apr. 15, 2014 to Gubbens et al., and U.S. Pat. No. 8,716,662 issued May 6, 2014 to MacDonald et al., which are incorporated by reference as if fully set forth herein.

Although the electron column is shown in FIG. 1 as being configured such that the electrons are directed to the specimen at an oblique angle of incidence and are scattered from the specimen at another oblique angle, the electron beam may be directed to and scattered from the specimen at any suitable angles. In addition, the electron beam tool may be configured to use multiple modes to generate output for the specimen (e.g., with different illumination angles, collection angles, etc.). The multiple modes of the electron beam tool may be different in any output generation parameters of the tool.

Computer subsystem 124 may be coupled to detector 134 in any suitable manner known in the art. Computer subsystem 124 may be configured to determine information for the lithography process using output generated by detector 134, which may be performed as described further herein. Computer subsystem 124 may be configured to perform any additional step(s) described herein. A system that includes the tool shown in FIG. 1 may be further configured as described herein.

Computer subsystem 124 (as well as other computer subsystems described herein) may also be referred to herein as computer system(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer subsystem, then the different computer subsystems may be coupled to each other such that images, data, information, instructions, etc. can be sent between the computer subsystems. For example, computer subsystem 124 may be coupled to another computer system(s) (not shown) by any suitable transmission media, which may include any suitable wired and/or wireless transmission media known in the art. Two or more of such computer subsystems may also be effectively coupled by a shared computer-readable storage medium (not shown).

Some examples of suitable metrology processes that may be performed by the metrology tool shown in FIG. 1 include, but are not limited to, cross-sectional SEM, cross-sectional transmission electron microscopy (TEM), and top-down SEM. Such metrology processes may be performed in any suitable manner known in the art. The metrology process and tool and the metrology measurements generated for the specimen may vary depending on the lithography process and the specimen metrological characteristics of interest (e.g., which characteristics “matter” in the successful fabrication of the patterned features, which characteristics can be used to determine parameter(s) of the lithography process as described herein, etc.).

FIG. 1 is provided herein to generally illustrate a configuration of an electron beam tool that may be included in the embodiments described herein. The electron beam tool configuration described herein may be altered to optimize the performance of the tool as is normally performed when designing a commercial system. In addition, the systems described herein may be implemented using an existing tool (e.g., by adding functionality described herein to an existing tool) such as tools that are commercially available from KLA Corp., Milpitas, Calif. For some such systems, the methods described herein may be provided as optional functionality of the system (e.g., in addition to other functionality of the system). Alternatively, the system described herein may be designed “from scratch” to provide a completely new system.

Although the tool is described above as being a light or electron beam tool, the tool may be an ion beam tool. Such a tool may be configured as shown in FIG. 1 except that the electron beam source may be replaced with any suitable ion beam source known in the art. In addition, the tool may include any other suitable ion beam tool such as those included in commercially available focused ion beam (FIB) systems, helium ion microscopy (HIM) systems, and secondary ion mass spectroscopy (SIMS) systems.

Instead of an electron beam tool, the one or more characteristics of the specimen may be generated by a light-based tool. FIG. 2 illustrates one embodiment of a system that includes various light-based tools, which may be included in the embodiments described herein for such purposes. The tools shown in FIG. 2 are described in more detail in U.S. Pat. No. 6,515,746 to Opsal et al., which is incorporated by reference as if fully set forth herein. Some of the non-essential details of the system presented in this patent have been omitted from the description corresponding to FIG. 2 presented herein. However, it is to be understood that the system illustrated in FIG. 2 may be further configured as described in this patent. In addition, it will be obvious upon reading the description of several embodiments provided herein that the system illustrated in FIG. 2 has been altered to improve upon the system described in U.S. Pat. No. 6,515,746 to Opsal et al.

One of the tools is configured as a broadband reflective spectrometer. Broadband reflective spectrometer (BRS) 230 simultaneously probes specimen 226 with multiple wavelengths of light. BRS 230 uses lens 232 and includes a broadband spectrometer 234 which can be of any type commonly known and used in the art. Lens 232 may be a transmissive optical component formed of a material such as calcium fluoride (CaF₂). Such a lens may be a spherical, microscope objective lens with a high numerical aperture (on the order of 0.90 NA) to create a large spread of angles of incidence with respect to the specimen surface, and to create a spot size of about one micron in diameter. Alternatively, lens 232 may be a reflective optical component. Such a lens may have a lower numerical aperture (on the order of 0.4 NA) and may be capable of focusing light to a spot size of about 10-15 microns. Spectrometer 234 shown in FIG. 2 includes lens 236, aperture 238, dispersive element 240, and detector array 242. Lens 236 may be formed of CaF₂.

During operation, probe beam 244 from light source 246 is collimated by lens 245, directed by mirror 243 through mirror 266 to mirror 286, which directs the light through mirror 248 to lens 232, which is then focused onto specimen 226 by lens 232. The light source may include any of the light sources described above. Lens 245 may be formed of CaF₂.

Light reflected from the surface of the specimen passes through lens 232 and is directed by mirror 248 (through mirror 250) to spectrometer 234. Lens 236 focuses the probe beam through aperture 238, which defines a spot in the field of view on the specimen surface to analyze. Dispersive element 240, such as a diffraction grating, prism, or holographic plate, angularly disperses the beam as a function of wavelength to individual detector elements contained in detector array 242.

The different detector elements measure the optical intensities of different wavelengths of light contained in the probe beam, preferably simultaneously. Alternately, detector 242 can be a charge-coupled device (“CCD”) camera or a photomultiplier with suitably dispersive or otherwise wavelength selective optics. It should be noted that a monochrometer could be used to measure the different wavelengths serially (one wavelength at a time) using a single detector element. Further, dispersive element 240 can also be configured to disperse the light as a function of wavelength in one direction, and as a function of the angle of incidence with respect to the specimen surface in an orthogonal direction, so that simultaneous measurements as a function of both wavelength and angle of incidence are possible. Computer subsystem 252 processes the intensity information measured by detector array 242.

Broadband spectroscopic ellipsometer (BSE) 254 is also configured to perform measurements of the specimen using light. BSE 254 includes polarizer 256, focusing mirror 258, collimating mirror 260, rotating compensator 262, and analyzer 264. In some embodiments, BSE 254 may be configured to perform measurements of the specimen using light provided by light source 246, light source 283, or another light source (not shown).

In operation, mirror 266 directs at least part of probe beam 244 to polarizer 256, which creates a known polarization state for the probe beam, preferably a linear polarization. Mirror 258 focuses the beam onto the specimen surface at an oblique angle, ideally on the order of 70 degrees to the normal of the specimen surface. Based upon well known ellipsometric principles, the reflected beam will generally have a mixed linear and circular polarization state after interacting with the specimen, based upon the composition and thickness of the specimen's film 268 and substrate 270.

The reflected beam is collimated by mirror 260, which directs the beam to rotating compensator 262. Compensator 262 introduces a relative phase delay δ (phase retardation) between a pair of mutually orthogonal polarized optical beam components. Compensator 262 is rotated at an angular velocity c about an axis substantially parallel to the propagation direction of the beam, preferably by electric motor 272. Analyzer 264, preferably another linear polarizer, mixes the polarization states incident on it. By measuring the light transmitted by analyzer 264, the polarization state of the reflected probe beam can be determined.

Mirror 250 directs the beam to spectrometer 234, which simultaneously measures the intensities of the different wavelengths of light in the reflected probe beam that pass through the compensator/analyzer combination. Computer subsystem 252 receives the output of detector 242, and processes the intensity information measured by detector 242 as a function of wavelength and as a function of the azimuth (rotational) angle of compensator 262 about its axis of rotation, to solve the ellipsometric values ψ and Δ as described in U.S. Pat. No. 5,877,859 to Aspnes et al., which is incorporated by reference as if fully set forth herein.

A system that includes the BRS and BSE described above may also include additional tool(s) configured to perform additional measurements of the specimen using light. For example, the system may include tools configured as a beam profile ellipsometer, a beam profile reflectometer, another optical subsystem, or a combination thereof.

Beam profile ellipsometry (BPE) is discussed in U.S. Pat. No. 5,181,080 to Fanton et al., which is incorporated by reference as if fully set forth herein. BPE 274 includes laser 283 that generates probe beam 284. Laser 283 may be a solid state laser diode from Toshiba Corp. which emits a linearly polarized 3 mW beam at 673 nm. BPE 274 also includes quarter wave plate 276, polarizer 278, lens 280, and quad detector 282. In operation, linearly polarized probe beam 284 is focused on specimen 226 by lens 232. Light reflected from the specimen surface passes up through lens 232 and mirrors 248, 286, and 288, and is directed into BPE 274 by mirror 290.

The position of the rays within the reflected probe beam correspond to specific angles of incidence with respect to the specimen's surface. Quarter-wave plate 276 retards the phase of one of the polarization states of the beam by 90 degrees. Linear polarizer 278 causes the two polarization states of the beam to interfere with each other. For maximum signal, the axis of polarizer 278 should be oriented at an angle of 45 degrees with respect to the fast and slow axis of quarter-wave plate 276. Detector 282 is a quad-cell detector with four radially disposed quadrants that each intercept one quarter of the probe beam and generate a separate output signal proportional to the power of the portion of the probe beam striking that quadrant.

The output signals from each quadrant are sent to computer subsystem 252. By monitoring the change in the polarization state of the beam, ellipsometric information, such as ψ and Δ, can be determined. To determine this information, computer subsystem 252 takes the difference between the sums of the output signals of diametrically opposed quadrants, a value which varies linearly with film thickness for very thin films.

Beam profile reflectometry (BPR) is discussed in U.S. Pat. No. 4,999,014 to Gold et al., which is incorporated by reference as if fully set forth herein. BPR 292 includes laser 283, lens 294, beam splitter 296, and two linear detector arrays 298 and 300 to measure the reflectance of the sample. In operation, linearly polarized probe beam 284 is focused onto specimen 226 by lens 232, with various rays within the beam striking the specimen surface at a range of angles of incidence. Light reflected from the specimen surface passes up through lens 232 and mirrors 248 and 286, and is directed into BPR 292 by mirror 288. The position of the rays within the reflected probe beam correspond to specific angles of incidence with respect to the specimen's surface. Lens 294 spatially spreads the beam two-dimensionally. Beam splitter 296 separates the S and P components of the beam, and detector arrays 298 and 300 are oriented orthogonal to each other to isolate information about S and P polarized light. The higher angles of incidence rays will fall closer to the opposed ends of the arrays. The output from each element in the diode arrays will correspond to different angles of incidence. Detectors arrays 298 and 300 measure the intensity across the reflected probe beam as a function of the angle of incidence with respect to the specimen surface. Computer subsystem 252 receives the output of detector arrays 298 and 300, and derives the thickness and refractive index of thin film layer 268 based on these angular dependent intensity measurements by utilizing various types of modeling algorithms. Optimization routines which use iterative processes such as least square fitting routines are typically employed.

The system shown in FIG. 2 may also include additional components such as detector/camera 302. Detector/camera 302 is positioned above mirror 290, and can be used to view reflected beams off of specimen 226 for alignment and focus purposes.

In order to calibrate BPE 274, BPR 292, BRS 230, and BSE 254, the system may include wavelength stable calibration reference ellipsometer 304 used in conjunction with a reference sample (not shown), which may be any appropriate sample of known parameters.

Ellipsometer 304 includes light source 306, polarizer 308, lenses 310 and 312, rotating compensator 314, analyzer 316, and detector 318. Compensator 314 is rotated about an axis substantially parallel to the propagation direction of beam 320, preferably by electric motor 322. The compensator can be located either between the specimen and the analyzer (as shown in FIG. 2) or between the specimen and polarizer 308. Polarizer 308, lenses 310 and 312, compensator 314, and polarizer 316 are all optimized in their construction for the specific wavelength of light produced by light source 306, which maximizes the accuracy of the ellipsometer.

Light source 306 produces a quasi-monochromatic probe beam 320 having a known stable wavelength and stable intensity. This can be done passively, where light source 306 generates a very stable output wavelength which does not vary over time (i.e., varies less than 1%). Examples of passively stable light sources are a helium-neon laser, or other gas discharge laser systems. Alternately, a non-passive system can be used where the light source includes a light generator (not shown) that produces light having a wavelength that is not precisely known or stable over time, and a monochrometer (not shown) that precisely measures the wavelength of light produced by the light generator. Examples of such light generators include laser diodes, or polychromatic light sources used in conjunction with a color filter such as a grating. In either case, the wavelength of beam 320, which is a known constant or measured by a monochrometer, is provided to computer subsystem 252 so that ellipsometer 304 can accurately calibrate the optical measurement devices in the system.

Operation of ellipsometer 304 during calibration is further described in U.S. Pat. No. 6,515,746. Briefly, beam 320 enters detector 318, which measures the intensity of the beam passing through the compensator/analyzer combination. Computer subsystem 252 processes the intensity information measured by detector 318 to determine the polarization state of the light after interacting with the analyzer, and therefore the ellipsometric parameters of the specimen. This information processing includes measuring beam intensity as a function of the azimuth (rotational) angle of the compensator about its axis of rotation. This measurement of intensity as a function of compensator rotational angle is effectively a measurement of the intensity of beam 320 as a function of time, since the compensator angular velocity is usually known and constant.

By knowing the composition of the reference sample, and by knowing the exact wavelength of light generated by light source 306, the optical properties of the reference sample such as film thickness d, refractive index and extinction coefficients, etc., can be determined by ellipsometer 304. Once the thickness d of the film has been determined by ellipsometer 304, then the same sample is probed by the other optical measurement devices BPE 274, BPR 292, BRS 230, and BSE 254 which measure various optical parameters of the sample. Computer subsystem 252 then calibrates the processing variables used to analyze the results from these optical measurement devices so that they produce accurate results. In the above described calibration techniques, all system variables affecting phase and intensity are determined and compensated for using the phase offset and reflectance normalizing factor discussed in U.S. Pat. No. 6,515,746, thus rendering the optical measurements made by these calibrated optical measurement devices absolute.

The above described calibration techniques are based largely upon calibration using the derived thickness d of the thin film. However, calibration using ellipsometer 304 can be based upon any of the optical properties of the reference sample that are measurable or determinable by ellipsometer 304 and/or are otherwise known, whether the sample has a single film thereon, has multiple films thereon, or even has no film thereon (bare sample).

In some embodiments, the tools may have at least one common optical component. For example, lens 232 is common to BPE 274, BPR 292, BRS 230, and BSE 254. In a similar manner, mirrors 243, 266, 286, and 248 are common to BPE 274, BPR 292, BRS 230, and BSE 254. Ellipsometer 304, as shown in FIG. 2, does not have any optical components that are common to the other tools. Such separation from the other tools may be appropriate since the ellipsometer is used to calibrate the other tools.

As further noted above, the tool may be configured to have multiple modes. In general, a “mode” is defined by the values of parameters of the tool used to generate output for the specimen. Therefore, modes that are different may be different in the values for at least one of the output generation parameters of the tool (other than position on the specimen at which the output is generated). For example, for a light-based tool, different modes may use different wavelengths of light. The modes may be different in the wavelengths of light directed to the specimen as described further herein (e.g., by using different light sources, different illumination channels, different spectral filters, etc. for different modes).

The multiple modes may also be different in illumination and/or collection/detection. For example, as described further above, the tool may include multiple detectors. One of the detectors may be used for one mode and another of the detectors may be used for another mode. Furthermore, the modes may be different from each other in more than one way described herein (e.g., different modes may have one or more different illumination parameters and one or more different detection parameters). In addition, the multiple modes may be different in perspective, meaning having either or both of different angles of incidence and angles of collection, which are achievable as described further above. The tool may be configured to scan the specimen with the different modes in the same scan or different scans, e.g., depending on the capability of using multiple modes to scan the specimen at the same time.

As noted above, the tool may be configured for directing energy (e.g., light, electrons) to and/or scanning energy over a physical version of the specimen thereby generating actual output for the physical version of the specimen. In this manner, the tool may be configured as an “actual” tool, rather than a “virtual” tool. However, a storage medium and/or other computer subsystems (not shown) may be configured as a “virtual” tool. In particular, the storage medium and computer system(s) are not part of a tool and do not have any capability for handling the physical version of the specimen but may be configured as a virtual metrology tool that performs metrology-like functions using stored detector output. Systems and methods configured as “virtual” tools are described in commonly assigned U.S. Pat. No. 8,126,255 issued on Feb. 28, 2012 to Bhaskar et al., U.S. Pat. No. 9,222,895 issued on Dec. 29, 2015 to Duffy et al., and U.S. Pat. No. 9,816,939 issued on Nov. 14, 2017 to Duffy et al., which are incorporated by reference as if fully set forth herein. The embodiments described herein may be further configured as described in these patents

In general, the tool is configured as a metrology subsystem. As described above, the tools shown in FIGS. 1-2 may be configured as metrology tools. In the field of semiconductor metrology, a metrology tool may include an illumination subsystem which illuminates a target, a collection subsystem which captures relevant information provided by the illumination subsystem's interaction (or lack thereof) with a target, device or feature, and a computer subsystem which analyzes the information collected using one or more algorithms. Metrology tools can be used to measure structural and material characteristics (e.g., material composition, dimensional characteristics of structures and films such as film thickness and/or critical dimensions (CDs) of structures, overlay, etc.) associated with various semiconductor fabrication processes. These measurements are used to facilitate process control and/or yield efficiencies in the manufacture of semiconductor dies.

The metrology tool can include one or more hardware configurations which may be used in conjunction with certain embodiments described herein to, e.g., measure the various aforementioned semiconductor structural and material characteristics. Examples of such hardware configurations include, but are not limited to, the following.
1. Spectroscopic ellipsometer (SE)
2. SE with multiple angles of illumination
3. SE measuring Mueller matrix elements (e.g. using rotating compensator(s))
4. Single-wavelength ellipsometers
5. Beam profile ellipsometer (angle-resolved ellipsometer)
6. Beam profile reflectometer (angle-resolved reflectometer)
7. Broadband reflective spectrometer (spectroscopic reflectometer)
8. Single-wavelength reflectometer
9. Angle-resolved reflectometer
10. Imaging system
11. Scatterometer (e.g. speckle analyzer)

The hardware configurations can be separated into discrete operational systems. On the other hand, one or more hardware configurations can be combined into a single tool. One example of combining multiple hardware configurations into a single tool is shown in FIG. 2, which may be further configured as described in U.S. Pat. No. 7,933,026 to Opsal et al., which is incorporated by reference as if fully set forth herein. The systems described herein may be further configured as described in this reference.

FIG. 2 shows, for example, a schematic of an exemplary metrology tool that comprises: a) a BSE (i.e., 254); b) a SE (i.e., 304) with rotating compensator (i.e., 314); c) a BPE (i.e., 274); d) a BPR (i.e., 292); e) a BRS (i.e., 230); and f) a deep ultraviolet reflective spectrometer (i.e., 230). In addition, there are typically numerous optical elements in such systems, including certain lenses, collimators, mirrors, quarter-wave plates, polarizers, detectors, cameras, apertures, and/or light sources. The wavelengths for optical tools can vary from about 120 nm to 3 microns. For non-ellipsometer tools, signals collected can be polarization-resolved or unpolarized. FIG. 2 provides an illustration of multiple metrology heads integrated on the same tool. However, in many cases, multiple metrology tools are used for measurements on a single or multiple metrology targets, which is described, e.g. in U.S. Pat. No. 7,478,019 to Zangooie et al, which is incorporated by reference as if fully set forth herein. The embodiments described herein may be further configured as described in this reference.

The illumination subsystem of the certain hardware configurations includes one or more light sources. The light source may generate light having only one wavelength (i.e., monochromatic light), light having a number of discrete wavelengths (i.e., polychromatic light), light having multiple wavelengths (i.e., broadband light) and/or light that sweeps through wavelengths, either continuously or hopping between wavelengths (i.e., tunable sources or swept sources). Examples of suitable light sources include, but are not limited to, a white light source, an ultraviolet (UV) laser, an arc lamp or an electrode-less lamp, a laser sustained plasma (LSP) source such as those commercially available from Energetiq Technology, Inc., Woburn, Massachusetts, a supercontinuum source (such as a broadband laser source) such as those commercially available from NKT Photonics Inc., Morganville, New Jersey, or shorter-wavelength sources such as x-ray sources, extreme UV sources, or some combination thereof. The light source may also be configured to provide light having sufficient brightness, which in some cases may be a brightness greater than about 1 W/(nm cm² Sr). The metrology tool may also include a fast feedback to the light source for stabilizing its power and wavelength. Output of the light source can be delivered via free-space propagation, or in some cases delivered via optical fiber or light guide of any type.

The metrology tool may be designed to make many different types of measurements related to semiconductor manufacturing. Certain embodiments described herein may be applicable to such measurements. For example, in certain embodiments, the tool may measure characteristics of one or more targets, such as CDs, overlay, sidewall angles, film thicknesses, process-related parameters (e.g., focus and/or dose). The targets can include regions of interest that are periodic in nature such as, for example, gratings in a memory die. Targets can include multiple layers (or films) whose thicknesses can be measured by the metrology tool. Targets can include target designs placed (or already existing) on the specimen for use, e.g., with alignment and/or overlay registration operations. Certain targets can be located at various places on the specimen. For example, targets can be located within the scribe lines (e.g., between dies) and/or located in the die itself. Multiple targets may be measured (at the same time or at differing times) by the same or multiple metrology tools as described in U.S. Pat. No. 7,478,019 to Zangooie et al. The data from such measurements may be combined. Data from the metrology tool is used in the semiconductor manufacturing process for example to feed-forward, feed-backward and/or feed-sideways corrections to the process (e.g. lithography, etch) and therefore, might yield a complete process control solution.

As semiconductor device pattern dimensions continue to shrink, smaller metrology targets are often required. The measurement accuracy and matching to actual device characteristics increase the need for device-like targets as well as in-die and even on-device measurements. Various metrology implementations have been proposed to achieve that goal. For example, focused beam ellipsometry based on primarily reflective optics is one of them and described in U.S. Pat. No. 5,608,526 to Piwonka-Corle et al., which is incorporated by reference as if fully set forth herein. The embodiments described herein may be further configured as described in this patent. Apodizers can be used to mitigate the effects of optical diffraction causing the spread of the illumination spot beyond the size defined by geometric optics. The use of apodizers is described in U.S. Pat. No. 5,859,424 to Norton, which is incorporated by reference as if fully set forth herein. The embodiments described herein may be further configured as described in this patent. The use of high-numerical-aperture tools with simultaneous multiple angle-of-incidence illumination is another way to achieve small-target capability. This technique is described, e.g., in U.S. Pat. No. 6,429,943 to Opsal et al, which is incorporated by reference as if fully set forth herein. The embodiments described herein may be further configured as described in this patent.

Other measurement examples may include measuring the composition of one or more layers of the semiconductor stack or the specimen, measuring certain defects on (or within) the specimen, and measuring the amount of photolithographic radiation exposed to the specimen. In some cases, the metrology tool and algorithm may be configured for measuring non-periodic targets, see e.g. U.S. Pat. No. 9,291,554 to Kuznetsov et al. issued Mar. 22, 2016 and U.S. Pat. No. 9,915,522 to Jiang et al. issued Mar. 13, 2018, which are incorporated by reference as if fully set forth herein. The embodiments described herein may be further configured as described in these patents.

Measurement of parameters of interest usually involves a number of algorithms. For example, optical interaction of the incident beam with the specimen is modeled using EM (electro-magnetic) solver and uses such algorithms as RCWA, FEM, method of moments, surface integral method, volume integral method, FDTD, and others. The target of interest is usually modeled (parametrized) using a geometric engine or, in some cases, a process modeling engine or a combination of both. The use of process modeling is described in U.S. Pat. No. 10,769,320 to Kuznetsov et al. issued Sep. 8, 2020, which is incorporated by reference as if fully set forth herein. The embodiments described herein may be further configured as described in this patent. A geometric engine is implemented, for example, in the AcuShape software product of KLA.

Collected data can be analyzed by a number of data fitting and optimization techniques and technologies including libraries, Fast-reduced-order models; regression; machine-learning algorithms such as neural networks, support-vector machines (SVM); dimensionality-reduction algorithms such as, e.g., PCA (principal component analysis), ICA (independent component analysis), LLE (local-linear embedding); sparse representation such as Fourier or wavelet transform; Kalman filter; algorithms to promote matching from same or different tool types, and others.

Collected data can also be analyzed by algorithms that do not include modeling, optimization and/or fitting as described, for example, in U.S. Pat. No. 10,591,406 to Bringoltz et al. issued Mar. 17, 2020, which is incorporated by reference as if fully set forth herein. The embodiments described herein may be further configured as described in this patent.

Computational algorithms are usually optimized for metrology applications with one or more approaches being used such as design and implementation of computational hardware, parallelization, distribution of computation, load-balancing, multi-service support, dynamic load optimization, etc. Different implementations of algorithms can be done in firmware, software, FPGA, programmable optics components, etc.

The data analysis and fitting steps usually pursue one or more of the following goals:
1. Measurement of CD, side wall angle (SWA), shape, stress, composition, films, bandgap, electrical properties, focus/dose, overlay, generating process parameters (e.g., resist state, partial pressure, temperature, focusing model), and/or any combination thereof;
2. Modeling and/or design of metrology systems; and
3. Modeling, design, and/or optimization of metrology targets.

The embodiments described herein configured for the field of semiconductor metrology are not limited to the hardware, algorithm/software implementations and architectures, and use cases summarized above.

The system includes a computer system (e.g., computer subsystem 124 shown in FIG. 1 or computer subsystem 252 shown in FIG. 2) and possibly one or more components (e.g., one or more components 104 shown in FIG. 1) executed by the computer system. The one or more components may be configured as described further herein and may be executed by the computer system in any suitable manner known in the art.

The computer system is configured for acquiring one or more characteristics of a specimen exposed to a pattern of light in a slit of the light scanned over the specimen during a lithography process. Acquiring the one or more characteristics of the specimen may or may not include generating the one or more characteristics. For example, the computer system may be configured for acquiring the characteristic(s) of a specimen from another method or system that generated the specimen characteristic(s), from a storage medium in which the specimen characteristic(s) have been stored by another method or system, etc. The embodiments described herein may acquire such metrology measurements in any suitable manner known in the art. In this manner, the embodiments described herein may not include the metrology tool.

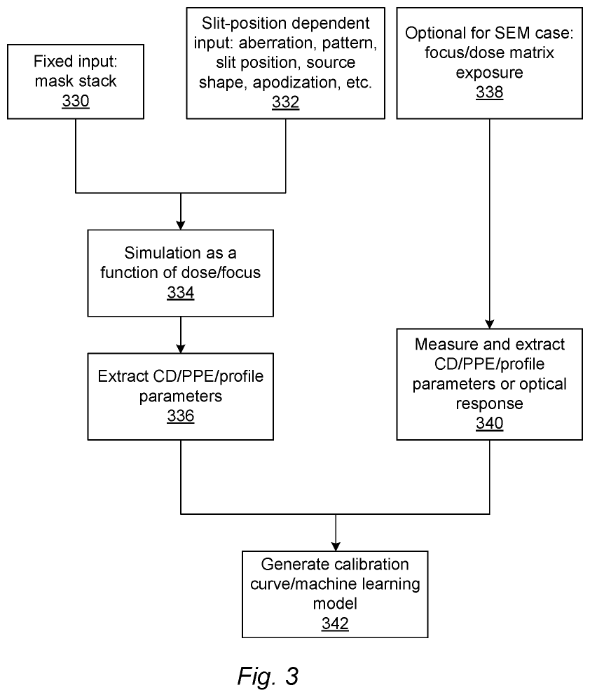

Regardless of whether or not the embodiments described herein generate the metrology measurements or acquire them from another system, method, or storage medium, the embodiments or another system or method may perform a product or monitor wafer exposure, as shown in step 400 of FIG. 4. The product or monitor wafer may include any suitable wafer known in the art. The exposure may be performed in any suitable manner known in the art and with any suitable lithography exposure tool known in the art, which generally includes subsystems often referred to as a scanner and lithography track.

In one embodiment, the light is extreme ultraviolet (EUV) light, and the lithography process is an EUV lithography process. For example, the embodiments described herein are particularly advantageous for EUV applications. EUV lithography tools can cost more than 100 million dollars. High NA EUV tools are expected to require a tighter focus control than the previous generation low NA EUV tools. Therefore, substantially robust focus control at every location within the exposure field will be important for reliable high volume production using these tools.

The computer system or another system or method may then measure and extract characteristics of the specimen such as CD/pattern profile error (PPE)/profile parameters, optical response, etc., as shown in step 402 of FIG. 4. In this manner, the systems described herein or another or system or method may generate “metrology measurements” for the specimen, which is defined herein as characteristic(s) of the specimen that are measured in an actual metrology process performed on a physical version of the specimen. Metrology measurements are usually quantitative in nature. Quantitative metrology measurements may be characteristics of specimens that are inherently matrix/vector valued or gauge metrics, which are scalar valued metrics. Quantitative metrology measurements may include, but are not limited to, CDs such as width and/or depth of a patterned feature formed on the specimen, but may also or alternatively include any others that may be related to parameters of the lithography process such as, but not limited to, side wall angle (SWA), line edge roughness (LER), line width roughness (LWR), tilt, pitch, contour related information such as sidewall shape, footing curvature, shoulder curvature, resist shrink, etc., of such a patterned feature, thickness of a film formed on the specimen, and surface roughness of such a film.

The computer system is also configured for determining one or more parameters with which the lithography process was performed at two or more of different positions within the slit based on the acquired one or more characteristics and a predetermined relationship between the one or more parameters at the different positions within the slit and one or more simulated characteristics of the specimen at different positions on the specimen corresponding to the different positions within the slit. For example, as described further herein, the predetermined relationship may be configured as a calibration curve or a machine learning (ML) model (e.g., ML model 106 shown in FIG. 1 included in component(s) 104 executed by computer subsystem 124), but the predetermined relationship may have any other form or format such as an algorithm or function. As shown in step 404 of FIG. 4, the determining one or more parameters step may include applying a calibration curve/ML model to the measured and extracted parameters from step 402. The computer system may then output the determined one or more parameters as shown in step 406 as output focus/dose setting.

The embodiments described herein may or may not be configured for generating the predetermined relationship used in the determining one or more parameters step. For example, the computer system may generate the predetermined relationship in one or more ways described further herein. However, another system or method may generate the predetermined relationship, and the computer system may then use the predetermined relationship as described herein. In one such embodiment, the other system or method may generate and store the predetermined relationship in a computer-readable storage medium accessible by the computer system, which may include any of the computer-readable storage media described herein. In addition or alternatively, the other system or method may generate and store the predetermined relationship in a recipe used by the embodiments described herein (e.g., by storing a file name, location, etc., for the predetermined relationship or storing the predetermined relationship in the recipe itself). In this manner, different systems may generate and use the predetermined relationship, or one system may both generate and use the predetermined relationship.

The predetermined relationship may also be generated and then updated as appropriate. For example, for a new layer, the available structures that are measured for the focus metrology may be simulated at different positions within the exposure slit through focus. The resulting behavior through focus may then be used to generate a focus metrology model that can be used as described herein to convert raw measurement results into a focus value at the different slit positions. Since lens aberrations (but also source shape, apodization, etc.) can change over time, the implementation may involve an initial calibration and a regular re-calibration using updated lens aberration (or other scanner) information.

The predetermined relationship may be generated by applying a computational model to retrieve CD and PPE information through focus at any slit position, pattern, and mask stack accounting for mask 3D effects and their variation through slit. One example of possible mask 3D effects include that, due to the incident chief ray angle on the mask in an EUV scanner, horizontal features are usually more sensitive to focus errors than vertical features. Generating the predetermined relationship is performed for calibration through simulation The simulation is performed to find CD, PPE, and possibly other effects as a function of focus.

In one embodiment, the computer system is configured for generating a calibration curve responsive to the predetermined relationship, and determining the one or more parameters includes applying the acquired characteristic(s) to the calibration curve. In other words, the relationship may be embodied as a calibration curve. The calibration curve may be a focus response curve, which describes how the measured signal (value of one or multiple metrology parameters) reacts to defocus. Inverted, the calibration curve describes how focus can be determined from the measured signal. The calibration curve may have any suitable form or format known in the art.

In another embodiment, determining the parameter(s) includes inputting the acquired one or more characteristics into a machine learning (ML) model configured for learning the predetermined relationship from training data including the one or more parameters at the different positions within the slit and the one or more simulated characteristics of the specimen at the different positions on the specimen. For example, the embodiments described herein may be configured for training a model using multi-parameter regression and/or ML to correlate (simulated and/or experimental) CD and PPE data through slit with scanner defocus. In this manner, the simulation model may be made more exact. As an example, the simulation may determine that a certain CD parameter, CD1, changes with x per nm defocus and another parameter, CD2,changes with y per nm defocus. Focus can then be determined with the function: focus 32 f(x*CD1, y*CD2). But experimental data may show that this is not completely accurate and that the true function may be, for example, Focus=f(((x*delta_x)*CD1+Delta1)+((y*delta_y)*CD2+Delta2)+Delta3). In general, the ML model may have any suitable form, architecture, parameters, etc. known in the art. For example, the ML model may be a convolutional neural network (CNN) or any model that can learn to predict focus error from input metrology measurements.

In some embodiments, the one or more parameters determined for the lithography process include focus and dose of the lithography process during exposure of the specimen. For example, focus and dose of the lithography process used during exposure of the specimen may be the most interesting and important parameters that can be determined by the embodiments described herein. In particular, these are the parameters that are most likely to drift or change on the lithography tool and most frequently cause variation in the specimens printed with the pattern of light. However, it is conceivable that the embodiments described herein may be configured for determining any other parameters with which the lithography process was performed on the specimen if those parameters have been used to determine the relationship as described herein.

In just one such example, the relationship described herein may be generated with simulated characteristics of the specimen for different parameters of the lithography process like light source shape. In some instances, the light source shape may change over time due to variations in the shape of the plasma used to generate the light. Based on some a priori information then about how the light source shape may vary over time, the light source shape information may be used to generate the simulated characteristic(s) described herein. The relationship may therefore be generated from the light source shape information and the associated simulated characteristic(s) and can then be used to output light source shape information in addition to any other parameter(s) described herein.

In another embodiment, the acquired one or more characteristics from which the one or more parameters are determined include the one or more characteristics of the specimen acquired at the two or more of the different positions within the slit. For example, for the embodiments described herein, it may be advantageous (but not required) to perform metrology measurements at multiple positions on the specimen corresponding to different positions within the slit. Therefore, the characteristics of the specimen can be determined as a function of slit position, which can possibly aid in determining the within-slit parameters with which the lithography process was performed on the specimen.

In an additional embodiment, the acquired one or more characteristics from which the one or more parameters are determined at the two or more of the different positions within the slit include only the one or more characteristics of the specimen acquired at only one of the different positions within the slit. For example, instead of measuring multiple positions on the specimen corresponding to the different positions within the slit, the specimen may be measured at only one position corresponding to only one within slit position. However, the characteristics measured at just that one specimen location may be sufficient to determine the parameters with which the lithography process was performed on the specimen as a function of within slit position. In other words, as described further herein, the embodiments can extract substantially accurate focus (and/or other parameter) information at any slit position and any pattern geometry and with only experimental data from a nominal slit position (e.g., center slit) and using simulation to predict the offset of the relationship (e.g., via calibration curve(s)).

In a further embodiment, the one or more simulated characteristics are generated for one or more predetermined parameters of the lithography process, the one or more predetermined parameters include one or more predetermined slit-position dependent parameters, and the one or more predetermined slit-position dependent parameters include focus and dose of the lithography process, shape of a light source configured for generating the light, one or more apodization parameters of a tool configured for exposing the specimen to the pattern of the light in the lithography process, and patterned features printed on the specimen in the lithography process. For example, simulations can be performed to predict CD and PPE through focus and can predict these parameters through slit and pattern. The predetermined slit-position dependent parameters may include acquired illuminator information from multiple points across the slit during a step to scan process in an EUV lithography process.

In one such embodiment, the one or more predetermined slit-position dependent parameters include aberration information for the tool generated for multiple positions within the slit, and the aberration information is generated by a metrology subsystem of the tool. For example, aberration information that is readily available from the on-board aberration metrology system in the scanner can be used as input to further refine the accuracy. Such aberration measurement is typically available from multiple points across the slit (e.g., thirteen points). The predetermined slit-position dependent parameters may include acquired aberration information from multiple points across the slit during a step to scan process in an EUV lithography process. Part of the lens aberrations may be determined at runtime by the scanner. More detailed information may be found by experiment. In most cases, there will not be updates to the model at runtime. Instead, there would likely be fixed aberrations with periodic updates. The aberration information across the slit may be an important input to the computations described herein.

In another such embodiment, the one or more predetermined parameters include one or more predetermined slit-position independent parameters, and the one or more predetermined slit-position independent parameters include mask stack information for a mask used to expose the specimen to the pattern of the light in the lithography process. For example, simulations can be performed to predict CD and PPE through focus and predict these parameters through mask stack accounting for mask shadowing variation through slit.

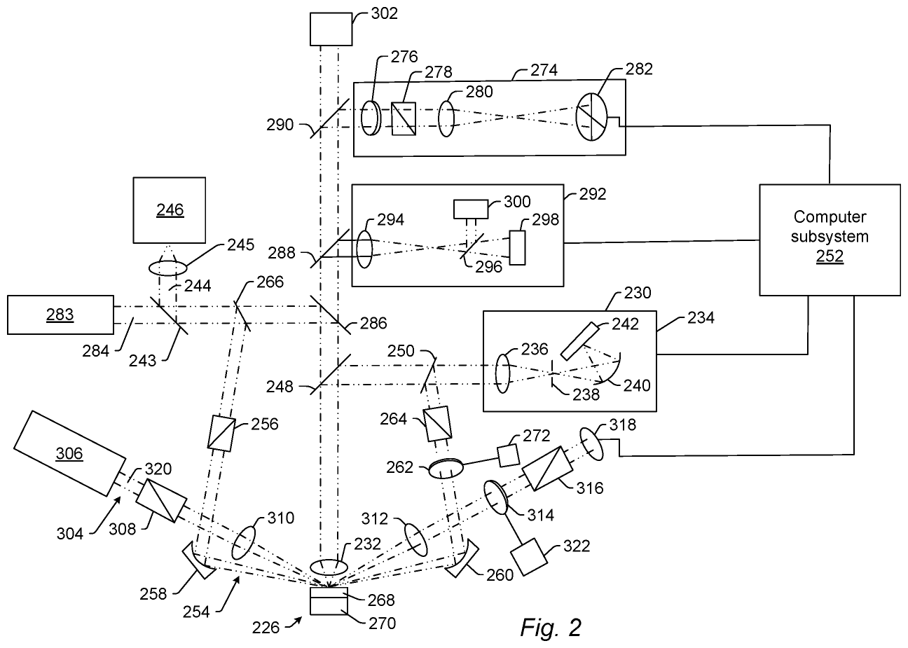

FIG. 3 illustrates steps that may be performed in the setup phase of the embodiments described herein. The computer system may acquire slit-position independent parameters including fixed inputs 330, which may include information for the mask stack of the mask/reticle that will be used to expose the specimen to the pattern of light in the lithography process. The mask stack information may be acquired in any suitable manner, e.g., from a fab database, and may have any suitable form or format. The computer system may also acquire slit-position dependent parameter input, which may include, but is not limited to, aberration, pattern, slit position, source shape, apodization, etc. These parameters may be acquired as described further herein and may have any form or format known in the art.

The computer system may input the fixed input and the slit-position dependent parameters into simulation 334, which is performed as a function of dose/focus of the lithography process. The simulations may be performed as described further herein. The computer system may then extract CD/PPE/profile parameters in step 336 from the simulation results. The extracted CD/PPE/profile parameters are the one or more simulated characteristics described herein. The CD/PPE/profile parameters and any other simulated characteristics described herein may be extracted from the simulation results in any suitable manner. For example, the simulations may generate simulated images of specimens patterned with the fixed and slit-position dependent inputs. The computer system may then input the simulated images into any suitable metrology method or algorithm known in the art. In this manner, the simulated images may be used in the same manner as any other images for metrology of the simulated specimen.

The computer system may also generate a calibration curve and/or ML model, as shown in step 342. In other words, the computer system may generate a relationship described herein. The relationship may be generated by associating the slit-position dependent inputs with the corresponding extracted CD/PPE/profile parameters. This step may be performed as described herein or in any other suitable manner known in the art. The relationship/calibration curve/ML model may then be used as described further herein for predicting or determining one or more slit-position dependent parameters from metrology results generated for a specimen exposed to the pattern of light in the lithography process.

In some embodiments, the one or more characteristics of the specimen are generated by a SEM. For example, the embodiments described herein enable application of simulated PPE through slit to SEM-based focus metrology. In addition, the embodiments described herein provide SEM-based focus metrology analysis to demonstrate through slit effects. In one such embodiment, the predetermined relationship is generated without experimental data. For example, for SEM-based focus metrology, there would potentially be the possibility to calibrate completely on simulation data using measured aberration data from the scanner. In other words, the computer system may determine the focus response of the measurement or calibrate how the measurement reacts to defocus. CD and PPE variation can be calculated as a function of dose, focus, slit position, and aberration for each pattern and mask stack. The data can be directly compared to experimental measurements on wafer. In this manner, one significant improvement and advantage of the embodiments described herein is that they are capable of extracting substantially accurate focus information at any slit position and any pattern geometry without the need for calibration based on experimental data.

In another such embodiment, the predetermined relationship is generated without simulating output of the SEM for the one or more simulated characteristics of the specimen. For example, a fully calibrated resist model may not be needed for this use case. Aerial image or image-in-resist simulation may provide the required effects, which significantly reduces the computational cost as well as on-wafer metrology efforts. In contrast, a resist model describes how after the process of exposing the resist, the resist profile reacts. Defocus impacts the aerial image (independent of the resist). Primary metrology parameters for the CDSEM based method are CD and PPE (resist profile is not so easily extracted by SEM). These metrology parameters can be extracted from the aerial image assuming a threshold model.

In another embodiment, the one or more characteristics of the specimen are generated by a light-based metrology tool, which may include any of the light-based metrology tool configurations described herein. In one such embodiment, the one or more simulated characteristics are generated at least in part with a model of one or more materials on the specimen during the lithography process. For example, optical methods may be calibrated by simulations only but the simulations may preferably include modeling of resist profiles and stack contributions. The SEM is not so strongly dependent on the resist profile as it “sees” the whole resist line. An optical method “sees” a portion of the resist and measures something based on the resist profiles over a larger area. Therefore, first, the resist behavior is preferably modeled relatively accurately, and second the measurement of that resist profile is preferably modeled, which tends to be not trivial.

Modeling the one or more materials on the specimen may include generating a 3D physical representation of the physical version of the specimen that would be generated by the lithography process for a given set of parameters of the process. For example, the computer system may generate a 3D physical representation of a specimen using data source(s) such as semiconductor device design information and/or a 3D model. The 3D physical representation of the physical version of the specimen is not a simulation of how the specimen will look to any one tool or system such as a metrology tool or system. Instead, the 3D physical representation is a simulation of how the specimen looks in specimen space (e.g., if a perfect 3D image of the specimen could be formed in an exactly accurate way, which is obviously not possible given the practical physical limitations of actual imaging systems).

Generally speaking, generating a 3D physical representation of the physical version of the specimen may include inputting a semiconductor device design into a model of a fabrication process to thereby generate a 3D physical representation of the physical version of the specimen having the semiconductor device design formed thereon. Generating a 3D physical representation of the physical version of the specimen may be performed using any models known in the art. One example of an empirically trained process model that may be used to generate a 3D physical representation of the physical version of the specimen includes SEMulator 3D, which is commercially available from Coventor, Inc., Cary, NC. An example of a rigorous lithography simulation model is Prolith, which is commercially available from KLA, and which can be used in concert with the SEMulator 3D product. Prolith provides the capability to predict placement and CD errors through slit. However, the 3D physical representation may be generated using any suitable model(s) of any of the process(es) involved in producing actual specimens from the design data.

In one such embodiment, the 3D physical representation is a specimen scale, 3D, TCAD, physical representation of the physical version of the specimen. For example, generating the 3D physical representation of the physical version of the specimen may include generating a wafer scale 3D, TCAD, physical representation of a physical wafer. TCAD is generally defined in the art as the use of computer simulations to develop and optimize semiconductor process technologies and devices. Generating such a 3D physical representation of the specimen may be performed using 3D technology modeling with TCAD software commercially available from Synopsys, Mountain View, Calif, and Silvaco, Santa Clara, Calif.

In another such embodiment, the one or more characteristics and the one or more simulated characteristics include one or more characteristics of output of the light-based metrology tool for the specimen and one or more simulated specimens, respectively. For example, for optical metrology, the link between extracted signal and the pattern (CD, placement error) may benefit from an additional step. The impact of variations in the pattern on the optical response may be simulated. In other words, the embodiments may be configured for generating simulated output of a metrology tool based on the simulated representations of the specimen generated as described above. One example of such simulated output is simulated specimen images that would be generated by a metrology tool for a specimen if printed in a lithography process with the process parameters (e.g., fixed input, slit-position dependent inputs, and focus/dose parameters) used for simulating the specimen. The one or more simulated characteristics may then be simply the simulated output of the metrology tool and/or one or more characteristics thereof.

In the embodiment described above, therefore, the simulated representation of the specimen may be used to generate the rendered output/image(s) that illustrate how the specimen would appear in the output/images of the specimen generated by a metrology tool. These rendered images may be produced using a model that can rigorously model the response of a metrology tool using an electromagnetic (EM) wave solver. Such simulations may be performed using any other suitable software, algorithm(s), method(s), or system(s) known in the art.

In other instances, the one or more components may include a deep learning (DL) type model that is configured for inferring the simulated output/image(s) from the design and/or from the simulated version of the specimen. In other words, the one or more components may include a DL model (not shown) that is configured to transform (by inference) one or more design files and/or one or more simulated 3D representations of the specimen into one or more rendered outputs/images that would be generated for the specimen by a metrology tool. The DL model may include any suitable DL model or network known in the art including, for example, a neural network, a CNN, a generative model, etc. The DL model may also be configured as described in commonly owned U.S. Patent Application Publication Nos. 2017/0140524 published May 18, 2017 by Karsenti et al., 2017/0148226 published May 25, 2017 by Zhang et al., 2017/0193400 published Jul. 6, 2017 by Bhaskar et al., 2017/0193680 published Jul. 6, 2017 by Zhang et al., 2017/0194126 published Jul. 6, 2017 by Bhaskar et al., 2017/0200260 published Jul. 13, 2017 by Bhaskar et al., 2017/0200264 published Jul. 13, 2017 by Park et al., 2017/0200265 published Jul. 13, 2017 by Bhaskar et al., 2017/0345140 published Nov. 30, 2017 by Zhang et al., 2017/0351952 published Dec. 7, 2017 by Zhang et al., 2018/0107928 published Apr. 19, 2018 by Zhang et al., 2018/0293721 published Oct. 11, 2018 by Gupta et al., 2018/0330511 published Nov. 15, 2018 by Ha et al., 2019/0005629 published Jan. 3, 2019 by Dandiana et al., and 2019/0073568 published Mar. 7, 2019 by He et al., which are incorporated by reference as if fully set forth herein. The embodiments described herein may be further configured as described in these patent application publications. In addition, the embodiments described herein may be configured to perform any steps described in these patent application publications.

The terms “design,” “design data,” and “design information” as used interchangeably herein generally refer to the physical design (layout) of an IC or other semiconductor device and data derived from the physical design through complex simulation or simple geometric and Boolean operations. The design may include any other design data or design data proxies described in commonly owned U.S. Pat. No. 7,570,796 issued on Aug. 4, 2009 to Zafar et al. and U.S. Pat. No. 7,676,077 issued on Mar. 9, 2010 to Kulkarni et al., both of which are incorporated by reference as if fully set forth herein. In addition, the design data can be standard cell library data, integrated layout data, design data for one or more layers, derivatives of the design data, and full or partial chip design data. Furthermore, the “design,” “design data,” and “design information” described herein refers to information and data that is generated by semiconductor device designers in a design process and is therefore available for use in the embodiments described herein well in advance of printing of the design on any physical specimens such as reticles and wafers.

In an additional such embodiment, the characteristic(s) include characteristic(s) of patterned features formed on the specimen during the lithography process and determined based on output of the light-based metrology tool for the specimen, and the simulated characteristic(s) include simulated characteristic(s) of simulated patterned features, formed on simulated specimen(s) during the lithography process, determined based on simulated output of the light-based metrology tool for the simulated specimen(s). In other words, this embodiment takes the above-described embodiment a step further and determines characteristics of the specimen from the simulated output of the metrology tool. For example, the characteristics of the specimen that was printed with the pattern of light in the lithography process may be measured by a metrology tool as described herein and may therefore be actual measured characteristics of a physical version of the specimen. These characteristics may include characteristics of a FEM wafer or any other specimen on which the lithography process was performed. The simulated characteristics of the simulated specimen may, however, be generated by inputting the simulated output of the metrology tool generated as described above into a metrology method or algorithm that therefore determines simulated characteristics (e.g., simulated CD/PPE/profile parameters, etc.) of the simulated specimens from the simulated output of the metrology tool. The actual and simulated characteristics of the actual and simulated specimens, respectively, may then be used with their associated process parameters to generate the relationship as described herein.

In a further such embodiment, the predetermined relationship is generated based on the simulated characteristic(s) and experimental data generated from additional specimen(s) exposed to the pattern of the light in the slit of the light scanned over the specimen during the lithography process performed with the parameter(s) of the lithography process. For example, the methods described herein may be improved by including experimental data. As described further above, for optical overlay metrology, the link between extracted signal and the underlying pattern (e.g., CD, PPE, etc.) may benefit from an additional step. Experimental data may either help to overcome inaccuracies in the settings (e.g., the resist model) or help to take into account contributions that are not included in the model (e.g., wafer topography). The impact of variations in the pattern on the optical response can be simulated as described above or may be trained (e.g., from a focus exposure matrix (FEM) wafer) using some form of ML. In this manner, the embodiments may augment the CD and PPE data set with experimental data.

As shown in step 338 of FIG. 3, an optional step for the SEM use case, but an advantageous step for the case in which the metrology is performed with a light-based tool, includes performing a focus/dose matrix exposure. This exposure may be performed in any suitable manner known in the art. In general, one or more specimens are exposed with the same pattern of light and in the same process, but with varying settings for focus and dose. In this manner, different dies (or other repeating patterned areas) on the specimen may be printed with different focus and dose, thereby providing a significant amount of experimental data for just one, or even a few, wafers. The embodiments described herein may then measure and extract CD/PPE, profile parameters, optical response, etc. of the one or more FEM wafers. For example, the one or more FEM wafers may be measured for any of the characteristics described herein by one or more of the metrology tools described herein.

The experimental data may then be used with the simulated results to generate a calibration curve/ML model in step 342 shown in FIG. 3. For example, the slit-position dependent parameters and the fixed input parameters may be associated with the simulated characteristics extracted in step 336. In addition, the focus/dose parameters used for exposure step 338 may be associated with the measured and extracted characteristics generated in step 340. All of the parameters and their associated specimen characteristics may then be input to step 342 to generate the relationship (e.g., calibration curve or ML model). The generated relationship may then be used as described further herein.

The experimental data generated from additional specimen(s) may include experimental data from only a nominal slit position (e.g., a center slit position). The simulations described herein may then be performed to predict offset of the relationship (e.g., calibration curves). One significant improvement and advantage of the embodiments described herein is therefore that they can extract substantially accurate focus information at any slit position and any pattern geometry with only experimental data from a nominal slit position (e.g., center slit) and performing simulation to predict offset of the calibration curves.

Additional significant improvements and advantages of the embodiments described herein include that currently through-slit illuminator variation and aberration variation effects are either ignored or calibrated only on an experimental basis. The embodiments described herein however allow removing or significantly reducing the need for calibration of the relationship and calibration updates of the relationship (for instance, as a result of ageing optics or changing scanner settings such as the illuminator or aberration injection). Instead, calibrating the relationship may be handled strictly based on simulation data or a combination of simulation and experimental data. Calibration means to obtain (e.g., a curve of) the focus response of the measurement system to defocus. This can be obtained through simulation or measurement. Therefore, the results may or may not be simulated. Indeed, after the curve is obtained, defocus can be determined by inversion.

The computer system is further configured for determining information for the lithography process based on the determined one or more parameters. For example, after a specimen has been exposed to a pattern of light in the lithography process and one or more characteristics of the specimen have been measured and acquired as described herein, the one or more characteristics may be input to the relationship (or the relationship may be applied to the one or more characteristics) to thereby determine the parameter(s) associated with the one or more characteristics. In other words, the measured characteristics of a specimen processed in a lithography tool may be used to determine one or more parameters of the process that was/were used to print that specimen. In general, how this determining step is performed may vary depending on the format of the relationship. In addition, although some embodiments of the relationship are described further herein, the relationship may have any form that can output one or more parameters from one or more input specimen characteristics.

Determining the information for the lithography process may therefore include determining one or more parameters of the lithography process that were used to expose the specimen to the pattern of light. The embodiments described herein may simply output those parameters for use in other steps that may be performed by another method or system or may be configured for using those output parameters for one or more other steps. For example, determining the information may also include determining if the lithography tool and process are performing within a specified process window for the process, which may be defined, for example, by a range of focus and dose parameter values. Determining if the lithography tool and process are performing within a specified process window may also or alternatively include comparing the one or more characteristics of the specimen to one or more predetermined acceptable ranges of the characteristic(s). In this manner, if the lithography tool and process produce a specimen that has one or more characteristics outside of a predetermined range, the determined one or more parameters of the lithography process may be used to determine corrections to the lithography process as described further herein.

In this manner, the systems described herein may be configured for simply monitoring the process. The determined information output by the systems described herein may then include only an indication of if the process was performed within specification. If the determined information indicates that the process was performed out of specification, another method or system may use that information to determine one or more corrections to the process. If the determined information indicates that the process was performed within specification, then another method or system may determine that the next specimen may be printed with the pattern of light by the lithography tool without any changes to the tool and/or process.

In one embodiment, determining the information for the lithography process includes determining one or more corrections to the lithography process based on the determined one or more parameters. In this manner, the embodiments described herein may be configured for computational based correction (or corrections based on computations) of aberrations and mask 3D effects for EUV scanner focus metrology and control. The computer subsystem may output corrected focus data for metrology and control of the EUV scanner. For example, the determining one or more parameters step may convert raw measurement results into a focus value at the different slit positions. These focus values can then be used to update the focus corrections used for the exposure of the next wafers. In general, the corrections may be determined from the information for the lithography process in any suitable manner known in the art and may be implemented as described further herein or in any other suitable manner known in the art.

In some embodiments, the computer system is configured for storing information for the one or more determined corrections and/or the altered lithography process resulting from applying the one or more determined corrections to the lithography process that was performed on the specimen. The computer system may be configured to store the information in a recipe or by generating a recipe for the altered lithography process. A “recipe” as that term is used herein can be generally defined as a set of instructions that can be used by a lithography tool to perform a lithography process on a specimen. In this manner, generating a recipe may include generating information for how a process is to be performed, which can then be used to generate the instructions for performing that process. The information for the altered lithography process that is stored by the computer system may include any information that can be used to identify and/or use a recipe for the altered lithography process (e.g., such as a file name and where it is stored, and the file may include information for the altered lithography process such as lithography process parameter values, etc.).

The computer system may be configured for storing the information for the altered lithography process in any suitable computer-readable storage medium. The information may be stored with any of the results and/or data described herein and may be stored in any manner known in the art. The storage medium may include any storage medium described herein or any other suitable storage medium known in the art. After the information has been stored, the information can be accessed in the storage medium and used by any of the method or system embodiments described herein, formatted for display to a user, used by another software module, method, or system, etc. For example, the embodiments described herein may generate a recipe as described above. That recipe may then be stored and used by the system or method (or another system or method) to perform a lithography process on one or more specimens.

The altered lithography process can also be sent to a lithography system (not shown) or a storage medium (not shown) accessible to the computer system and the lithography system. The lithography system may or may not be part of the system embodiments described herein. For example, the computer system described herein may be coupled to the lithography system, e.g., via one or more common elements such as a housing, a power supply, etc. The lithography system may include any lithography system described herein or known in the art. In this manner, the computer system may be configured to cause the lithography tool to perform the altered fabrication process on one or more specimens to thereby print the pattern on other specimen(s).

The embodiments described herein have a number of important advantages and improvements over currently used methods and systems that are provided by a number of new features of the embodiments described herein. For example, the embodiments described herein have important advantages and improvements for all lithography processes and especially EUV lithography processes. Focus control is expected to become even more important for EUV lithography compared to other currently used lithography processes. In addition, EUV lithography is relatively expensive so the cost for any rework caused by focus control errors will be relatively high. As such, relatively fast dispositioning of EUV errors will be substantially valuable for entities that perform or rely on EUV lithography. Having substantially robust, accurate, and fast methods for measuring and controlling focus is expected to provide significant advantages for such entities.

Each of the embodiments of each of the systems described above may be combined together into one single embodiment.

Another embodiment relates to a computer-implemented method for determining information for a lithography process. The method includes acquiring characteristic(s) of a specimen exposed to a pattern of light in a slit of the light scanned over the specimen during a lithography process. The method also includes determining parameter(s) with which the lithography process was performed at two or more of different positions within the slit based on the acquired characteristic(s) and a predetermined relationship between the parameter(s) at the different positions within the slit and simulated characteristic(s) of the specimen at different positions on the specimen corresponding to different positions within the slit. In addition, the method includes determining information for the lithography process based on the determined one or more parameters. The acquiring, determining one or more parameters, and determining information steps are performed by a computer system.

Each of the steps of the method may be performed as described further herein. The method may also include any other step(s) that can be performed by the system, computer system, and/or component(s), described herein. The computer system may be configured according to any of the embodiments described herein. The one or more components may also be configured according to any of the embodiments described herein. The method may be performed by any of the system embodiments described herein.

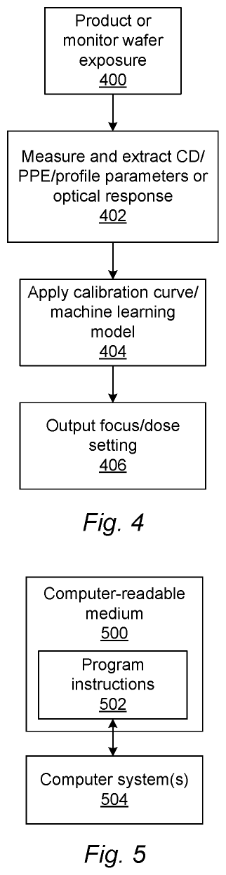

An additional embodiment relates to a non-transitory computer-readable medium storing program instructions executable on a computer system for performing a computer-implemented method for determining information for a lithography process. One such embodiment is shown in FIG. 5. In particular, as shown in FIG. 5, non-transitory computer-readable medium 500 includes program instructions 502 executable on computer system(s) 504. The computer-implemented method may include any step(s) of any method(s) described herein.

Program instructions 502 implementing methods such as those described herein may be stored on computer-readable medium 500. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), SSE (Streaming SIMD Extension) or other technologies or methodologies, as desired.

Computer system(s) 504 may be configured according to any of the embodiments described herein.

Further modifications and alternative embodiments of various aspects of the invention will be apparent to those skilled in the art in view of this description. For example, systems and methods for determining information for a lithography process are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A system configured for determining information for a lithography process, comprising:
a computer system configured for:
acquiring one or more characteristics of a specimen exposed to a pattern of light in a slit of the light scanned over the specimen during a lithography process;
determining one or more parameters with which the lithography process was performed at two or more of different positions within the slit based on the acquired one or more characteristics and a predetermined relationship between the one or more parameters at the different positions within the slit and one or more simulated characteristics of the specimen at different positions on the specimen corresponding to the different positions within the slit; and
determining information for the lithography process based on the determined one or more parameters.

2. The system of claim 1, wherein the light is extreme ultraviolet (EUV) light, and wherein the lithography process is an EUV lithography process.

3. The system of claim 1, wherein the acquired one or more characteristics from which the one or more parameters are determined comprise the one or more characteristics of the specimen acquired at the two or more of the different positions within the slit.

4. The system of claim 1, wherein the acquired one or more characteristics from which the one or more parameters are determined at the two or more of the different positions within the slit comprise only the one or more characteristics of the specimen acquired at only one of the different positions within the slit.

5. The system of claim 1, wherein the one or more characteristics and the one or more simulated characteristics comprise at least one of a critical dimension, pattern placement error, and profile parameter of patterned features printed on the specimen during the lithography process.

6. The system of claim 1, wherein the one or more simulated characteristics are generated for one or more predetermined parameters of the lithography process, wherein the one or more predetermined parameters comprise one or more predetermined slit-position dependent parameters, and wherein the one or more predetermined slit-position dependent parameters comprise focus and dose of the lithography process, shape of a light source configured for generating the light, one or more apodization parameters of a tool configured for exposing the specimen to the pattern of the light in the lithography process, and patterned features printed on the specimen in the lithography process.

7. The system of claim 6, wherein the one or more predetermined slit-position dependent parameters further comprise aberration information for the tool generated for multiple positions within the slit, and wherein the aberration information is generated by a metrology subsystem of the tool.

8. The system of claim 6, wherein the one or more predetermined parameters further comprise one or more predetermined slit-position independent parameters, and wherein the one or more predetermined slit-position independent parameters comprise mask stack information for a mask used to expose the specimen to the pattern of the light in the lithography process.

9. The system of claim 1, wherein the one or more characteristics of the specimen are generated by a scanning electron microscope (SEM), and wherein the predetermined relationship is generated without experimental data.

10. The system of claim 1, wherein the one or more characteristics of the specimen are generated by a SEM, and wherein the predetermined relationship is generated without simulating output of the SEM for the one or more simulated characteristics of the specimen.

11. The system of claim 1, wherein the one or more characteristics of the specimen are generated by a light-based metrology tool, and wherein the one or more simulated characteristics are generated at least in part with a model of one or more materials on the specimen during the lithography process.

12. The system of claim 1, wherein the one or more characteristics of the specimen are generated by a light-based metrology tool, and wherein the one or more characteristics and the one or more simulated characteristics comprise one or more characteristics of output of the light-based metrology tool for the specimen and one or more simulated specimens, respectively.

13. The system of claim 1, wherein the one or more characteristics of the specimen are generated by a light-based metrology tool, wherein the one or more characteristics comprise one or more characteristics of patterned features formed on the specimen during the lithography process and determined based on output of the light-based metrology tool for the specimen, and wherein the one or more simulated characteristics comprise one or more simulated characteristics of simulated patterned features, formed on one or more simulated specimens during the lithography process, determined based on simulated output of the light-based metrology tool for the one or more simulated specimens.

14. The system of claim 1, wherein the one or more characteristics of the specimen are generated by a light-based metrology tool, and wherein the predetermined relationship is generated based on the one or more simulated characteristics and experimental data generated from one or more additional specimens exposed to the pattern of the light in the slit of the light scanned over the specimen during the lithography process performed with the one or more parameters of the lithography process.

15. The system of claim 1, wherein the computer system is further configured for generating a calibration curve responsive to the predetermined relationship, and wherein determining the one or more parameters comprises applying the acquired one or more characteristics to the calibration curve.

16. The system of claim 1, wherein determining the one or more parameters comprises inputting the acquired one or more characteristics into a machine learning model configured for learning the predetermined relationship from training data comprising the one or more parameters at the different positions within the slit and the one or more simulated characteristics of the specimen at the different positions on the specimen.

17. The system of claim 1, wherein the one or more parameters determined for the lithography process comprise focus and dose of the lithography process during exposure of the specimen.

18. The system of claim 1, wherein determining the information for the lithography process comprises determining one or more corrections to the lithography process based on the determined one or more parameters.

19. A non-transitory computer-readable medium, storing program instructions executable on a computer system for performing a computer-implemented method for determining information for a lithography process, wherein the computer-implemented method comprises:
acquiring one or more characteristics of a specimen exposed to a pattern of light in a slit of the light scanned over the specimen during a lithography process;
determining one or more parameters with which the lithography process was performed at two or more of different positions within the slit based on the acquired one or more characteristics and a predetermined relationship between the one or more parameters at the different positions within the slit and one or more simulated characteristics of the specimen at different positions on the specimen corresponding to the different positions within the slit; and
determining information for the lithography process based on the determined one or more parameters.

20. A computer-implemented method for determining information for a lithography process, comprising:
acquiring one or more characteristics of a specimen exposed to a pattern of light in a slit of the light scanned over the specimen during a lithography process;
determining one or more parameters with which the lithography process was performed at two or more of different positions within the slit based on the acquired one or more characteristics and a predetermined relationship between the one or more parameters at the different positions within the slit and one or more simulated characteristics of the specimen at different positions on the specimen corresponding to the different positions within the slit; and
determining information for the lithography process based on the determined one or more parameters, wherein said acquiring, determining the one or more parameters, and determining the information are performed by a computer system.
